(19) United States
(12) Patent Application Publication
(10) Pub. No.: US 2011/0199735 A1
(43) Pub. Date: Aug. 18, 2011

(54) SUBSTRATE CONNECTING STRUCTURE AND ELECTRONIC DEVICE

(75) Inventor: Masahito Kawabata, Kanagawa (JP)

(73) Assignee: PANASONIC CORPORATION, Osaka (JP)

(21) Appl. No.: 13/124,093

(22) PCT Filed: Feb. 22, 2010
(86) PCT No.: PCT/JP2010/001156

§ 371 Date: Apr. 13, 2011

(30) Foreign Application Priority Data
Aug. 27, 2009 (JP) 2009-196717

(51) Int. Cl. H05K 7/20

(52) U.S. Cl. 361/721

(57) ABSTRACT

There is provided a substrate connecting structure capable of preventing occurrence of a connection failure, which would otherwise be caused by a non-uniform temperature rise within a connecting areas of circuit boards during thermocompression bonding. A substrate connecting structure 10 includes a printed circuit board 20 having a hard base material 21 with first and second faces, and a plurality of circuit patterns 23 arranged on the second face; a flexible circuit board 30 having a soft base material 31 with first and second faces and a plurality of circuit patterns 33 arranged on the second face; connecting sections (connecting areas) 24 and 34 that connect the circuit patterns 23 of the printed circuit board 20 and the circuit patterns 33 of the flexible circuit board 30 through a conductive connection material; a first heat conduction layer 52A that is arranged on the first face of the flexible circuit board 30 and that has a first heat conductivity conducted per unit time; and a second heat conduction layer 52B that is arranged on the first face of the flexible circuit board 30 while adjoining the first heat conduction layer 52A and that has a second heat conductivity conducted per unit time which is smaller than the first heat conductivity. The first and second heat conduction layers 52A and 52B oppose at least portions of the plurality of circuit patterns 33 of the flexible circuit board 30 through the base material of the flexible circuit board 30 and are arranged so as to extend over at least portions of the connecting areas and the area adjoining the connecting areas.

### TECHNICAL FIELD

The present invention relates to a substrate connecting structure for connecting circuit boards to each other through a conductive connection material, as well as to an electronic device having the substrate connecting structure.

### BACKGROUND ART

In an electronic device; for instance, a portable phone, a hard printed circuit board and a soft flexible circuit board are provided within an enclosure, and connecting sections of the circuit boards are electrically connected to each other. FIG. 14 shows a process of creating a substrate connecting structure.

As shown in FIG. 14, a printed circuit board 20 has a mount section 22 and a connection section (a connecting area) 24. A plurality of electronic components are mounted on a front face of a hard base material 21 opposing a flexible circuit board 30. In the connection section 24, a plurality of circuit patterns 23 are arranged side by side so as to extend over the mount section 22. A front face of the printed circuit board 20 and a back face that is the other side of the substrate are coated with a transparent cover-lay 25 (or a resist) that covers the mount section 22. The circuit patterns 23 are exposed on a front face side of the connection section 24 by opening the cover-lay 25.

The flexible circuit board 30 has, on a face of a soft base material 31 that is a side opposing the printed circuit board 20, a connection section 34 (a connecting area) in which a plurality of circuit patterns 33 are arranged side by side and an adjoining section 35 adjoining the connection section 34 along its widthwise direction.

As shown in FIG. 16, when the printed circuit board 20 and the flexible circuit board 30 are connected, an unillustrated ACF (anisotropic conductive film) is sandwiched between the connection section 24 of the printed circuit board 20 and the connection section 34 of the flexible circuit board 30, whereupon the connecting sections 24 and 34 are superposed one on top of the other so that an overlap exists between the circuit patterns 23 and 33. The connecting sections 24 and 34 are nipped in this state from the outside by means of a heat-press tool 12a and a receiving tool 12b of a thermocompression bonding jig 12, thereby applying pressure and heat to the connecting sections 24 and 34 for a predetermined period of time. The circuit patterns 23 and 33 are fixed together while remaining in plane contact with each other, by means of a melt, solidified ACF, whereupon the printed circuit board 20 and the flexible circuit board 30 are electrically connected together.

Several proposals have hitherto been made to make sure a connection formed from a conductive connection material during thermocompression bonding operation. For instance, in Patent Document 1, the thickness of a cover-lay on a back face of a connection section of a flexible circuit board is locally increased at a region close to a mount section of a printed circuit board, to thus pose difficulty in transmission of heat resultant from thermocompression bonding to a connection section of the printed circuit board and the region of the connection section of the flexible circuit board close to the mount section, thereby preventing occurrence of an increase in temperature of the location on the connection section close to the mount section and making the temperature of the connection section uniform.

In Patent Document 2, an opening is made in a shield on a back face of a flexible circuit board only at a position of a connection section of a circuit pattern, thereby facilitating transmission of heat of a thermocompression bonding tool to the connection section.

In Patent Document 3, a heat dissipation member that is symmetry with respect to a center line, like a triangular shape, is placed on a back face of a flexible circuit board close to a connection section of a circuit pattern on a front face of the circuit board. Heat generated during thermocompression bonding operation is controlled by the heat dissipation member, thereby making uniform a temperature of a connection section of a printed circuit board and a temperature of the connection section of the flexible circuit board.

In Patent Document 4, a dummy pattern is provided on a back face of a connection section of a flexible circuit board for each of conductor lines making up a circuit pattern of the flexible circuit board. Heat generated during thermocompression bonding operation is transmitted to the respective conductor lines by the corresponding dummy patterns, thereby implementing firm bonding.

### RELATED ART DOCUMENTS

### Patent Documents

Patent Document 1: WO 2007/072570

Patent Document 2: JP-A-06-090082

Patent Document 3: JP-A-2005-166780

Patent Document 4: JP-B-4-044440

### DISCLOSURE OF THE INVENTION

### Problem that the Invention is to Solve

Incidentally, in order to make the printed circuit board 20 compatible with a reduction in size and thickness of an enclosure, the mount section 22 and the connection section 24 are sometimes arranged out of alignment in the shape of the letter L, as shown in FIG. 14, rather than in alignment with each other. For this reason, when the connection section 24 of the printed circuit board 20 and the connection 34 of the connection section 34 are heated, a region 10A1 of the connecting sections 24 and 34 close to the mount section 22 of the printed circuit board 20 is likely to dissipate heat to the mount section 22 through the hard base material 21 as indicated by arrow Q1 as show in FIG. 15. In contrast to this, a region 10A2 remote from the mount section 22 is less likely to dissipate heat to the mount section 22 through the hard base material 21 as indicated by arrow Q2, so that heat builds up in this region. For this reason, as shown in FIG. 17, a temperature Tm1 of the region 10A1 of the connecting sections 24 and 34 close to the mount section 22; for instance, an a region designated by left registration mark m1, becomes lower and a temperature Tm2 of the region 10A2 remote from the mount section 22; for instance, a region designated by right registration mark m2, becomes higher. Thus, a heating temperature becomes non-uniform from the region 10A1 of the connecting sections 24 and 34 close to the mount region 22 to the region 10A2 remote from the mount section 22.

When excessive heating occurs in the region 10A2 of the connecting sections 24 and 34 remote from the mount section 22 for reasons of such a non-uniform heating temperature, the region 10A2 of the flexible circuit board 30 undergoes extension or spring back which would arise during cooling operation, thereby posing difficulty in establishing a highly accurate connection between the circuit patterns 23 and 33. In the meantime, when a heat deficiency has occurred in the region 10A1 of the connecting sections 24 and 34 close to the mount section 22, a-resin of an adhesive around the region 10A1 becomes insufficiently thermally set, thereby making it difficult to establish a firm connection between the circuit patterns 23 and 33.

A problem of connection quality attributable to a non-uniform heating temperature in the connection section, such as that mentioned above, also occurs when the circuit patterns 23 and 33 are connected together by use of solder. When solder in the region 10A2 of the connecting sections 24 and 34 remote from the mount section 22 is excessively heated, extension and burning of the flexible circuit board 30, enlargement of a solder alloy layer, and invasion of a copper foil making up the circuit patterns 23 and 33, and the like, occur in the region 10A2, which in turn raises a problem of connection quality, like embrittlement of a solder-bonded interface. A time that elapses before melted solder is cooled to a solidification temperature becomes longer, which results in deterioration of productivity of an electronic device. In the meantime, when a heat deficiency arises in the region 10A1 close to the mount section 22, solder becomes insufficiently melt, thereby making it difficult to establish a firm connection between the circuit patterns 23 and 33 at the region 10A1.

A problem of the invention is to provide a substrate connecting structure that makes it possible to prevent a non-uniform temperature increase in a connection region of circuit boards when two circuit boards are subjected to thermocompression bonding by use of a conductive connection material, thereby preventing occurrence of a connection failure.

### Means for Solving the Problem

A substrate connecting structure of the present invention includes: a first circuit board including a base material with first and second faces and a plurality of circuit patterns arranged on the second face; a second circuit board including a base material with first and second faces and a plurality of circuit patterns arranged on the second face; connecting areas that connect the circuit patterns of the first circuit board and the circuit patterns of the second circuit board through a conductive connection material; a first heat conduction layer that is arranged on the first face of the second circuit board and that has a first quantity of heat conducted per unit time; and a second heat conduction layer that is arranged on the first face of the second circuit board while adjoining the first heat conduction layer and that has a second quantity of heat conducted per unit time, the second quantity being smaller than the first quantity. The first and second heat conduction layers oppose at least part of the plurality of circuit patterns of the second circuit board through the base material of the second circuit board and are arranged so as to extend over at least part of the connecting areas and an area adjoining the connecting areas.

In the foregoing configuration, the range where the first heat conduction layer is arranged on the first face of the second circuit board is set to a region of the connecting area of the first circuit board and a region of the connecting area of the second circuit board where heat is likely to build up and to an area adjoining the connecting areas. Thus, heat in the regions of the connecting areas where heat is likely to build up during thermocompression bonding can be caused to propagate to the heat conduction layers, to thus be dissipated. Therefore, it is possible to well connect the circuit patterns of the first circuit board to the circuit patterns of the second circuit board by the conductive connection material while preventing a non-uniform increase in temperatures of the connecting areas of the circuit boards.

In one mode of the present invention, an area of the first heat conduction layer arranged in the area adjoining the connecting areas is greater than an area of the first heat conduction layer arranged in the at least part of the connecting areas.

The heat conduction layer of a larger area has large heat capacity, enables superior transmission of heat, and exhibits a greater heat dissipation effect. In the configuration, the area of the first heat conduction layer arranged in the area adjoining the connecting areas is made larger than the area of the first heat conduction layer arranged in portions of the connecting areas. Therefore, the heat built up in the portions of the connecting areas is effectively transmitted from the first heat conduction layer arranged in the portions of the connecting areas to the first heat conduction layer arranged in the area adjoining the connecting areas, to thus be dissipated to the outside.

In one mode of the present invention, an area of the second heat conduction layer arranged in the area adjoining the connecting areas is greater than an area of the second heat conduction layer arranged in the at least part of the connecting areas.

In the configuration, the area of the second heat conduction layer arranged in the area adjoining the connecting areas is larger than the area of the second heat conduction layer arranged in portions of the connecting areas. Hence, the heat in the portions of the connecting areas is effectively transmitted from the second heat conduction layer laid in the portions of the connecting areas to the second heat conduction layer laid in the area adjoining the connecting area, to thus be dissipated to the outside.

In one mode of the present invention, the conductive connection material is a hot melt conductive material or a thermosetting conductive resin.

In the configuration, the conductive connection material can be applied to the present invention regardless of whether the conductive connection material is solder (a hot melt conductive material) or an anisotropic conductive resin (a thermosetting conductive resin).

In one mode of the present invention, an opening window is provided in the connecting area of the second circuit board, registration marks are provided in the connecting area of the first circuit board and the connecting area of the second circuit board, and a state of overlap between the registration mark of the first circuit board and the registration mark of the second circuit board is observable through the opening window.

In the configuration, the circuit patterns of the first circuit board and the circuit patterns of the second circuit board can be aligned to each other while the registration marks of the first and second circuit boards are taken as signs.

In one mode of the present invention, the first and second heat conduction layers oppose all of the plurality of circuit patterns of the second circuit board and are arranged so as to extend over a substantial entirety of the connecting areas and the area adjoining the connecting areas.

In the configuration, the heat conduction layers are arranged over a substantial entirety of the connecting areas by means of the first and second heat conduction layers.

In one mode of the present invention, the first and second heat conduction layers are made of a conductive resin.

In the configuration, even a heat conduction layer made of a conductive resin can also be used for the first and second heat conductive layers.

In one mode of the present invention, the conductive resin is arranged also on a flexible substrate connected to the connecting areas.

In the configuration, heat transfer can be controlled by utilization of a shield of the flexible substrate connected to the connecting area of the second circuit board.

In one mode of the present invention, heat conductivity of a first material making up the first heat conduction layer is greater than heat conductivity of a second material making up the second heat conduction layer.

In the configuration, the first heat conduction layer and the second heat conduction layer can be made by changing heat conductivity of a material making up the heat conduction layers.

In one mode of the present invention, a quantity of conductive filler contained per unit volume in the first heat conduction layer is greater than a quantity of conductive filler per unit volume in the second heat conduction layer.

In the configuration, the first heat conduction layer and the second heat conduction layer can be formed by changing a quantity of conductive filler contained per unit volume in the heat conduction layer.

In one mode of the present invention, a thickness of the first heat conduction layer is greater than a thickness of the second heat conduction layer.

In the configuration, the first heat conduction layer and the second heat conduction layer can be made by changing the thickness of the heat conduction layer.

An electronic device of the present invention has the substrate connecting structure.

In the configuration, there can be produced an electronic device that exhibits superior quality of a connection between the circuit patterns of the first circuit board and the circuit patterns of the second circuit board.

### Advantage of the Invention

The present invention can provide a substrate connecting structure that enables prevention of occurrence of non-uniform temperature increases in connection regions of circuit boards when two circuit boards are thermally bonded by use of a conductive connection material and can also provide an electronic device having the substrate connecting structure.

### BRIEF DESCRIPTION OF THE DRAWINGS

FIG. 1 is an exploded perspective view showing a substrate connecting structure of a first embodiment of the present invention.

FIG. 2 is a flow chart for creating the substrate connecting structure.

FIG. 3 is a plan view of the substrate connecting structure.

FIG. 4 is a cross sectional view taken along line A-A′ shown in FIG. 3.

FIG. 5 is a graph schematically showing a temperature distribution of a connection section.

FIG. 6 is an exploded perspective view showing a substrate connecting structure of a second embodiment of the present invention.

FIG. 7 is a plan view of the substrate connecting structure.

FIG. 8 is a cross sectional view taken along line A-A′ shown in FIG. 7.

FIG. 9 is a plan view showing various examples of a substrate connecting structure of a third embodiment of the present invention.

FIG. 10 is a plan view showing various examples of a substrate connecting structure of a fourth embodiment of the present invention.

FIG. 11 is a view showing a substrate connecting structure of a fifth embodiment of the present invention.

FIG. 12 is a view showing a substrate connecting structure of a sixth embodiment of the present invention.

FIG. 13 is a view showing a substrate connecting structure of a seventh embodiment of the present invention.

FIG. 14 is a flow chart for creating a related art substrate connecting structure.

FIG. 15 is a plan view of the substrate connecting structure.

FIG. 16 is a cross sectional view taken along line A-A′ shown in FIG. 15.

FIG. 17 is a graph schematically showing a temperature distribution of a connection section.

### EMBODIMENTS FOR IMPLEMENTING THE INVENTION

Embodiments of a substrate connecting structure of the present invention are hereunder described by reference to the drawings.

### First Embodiment

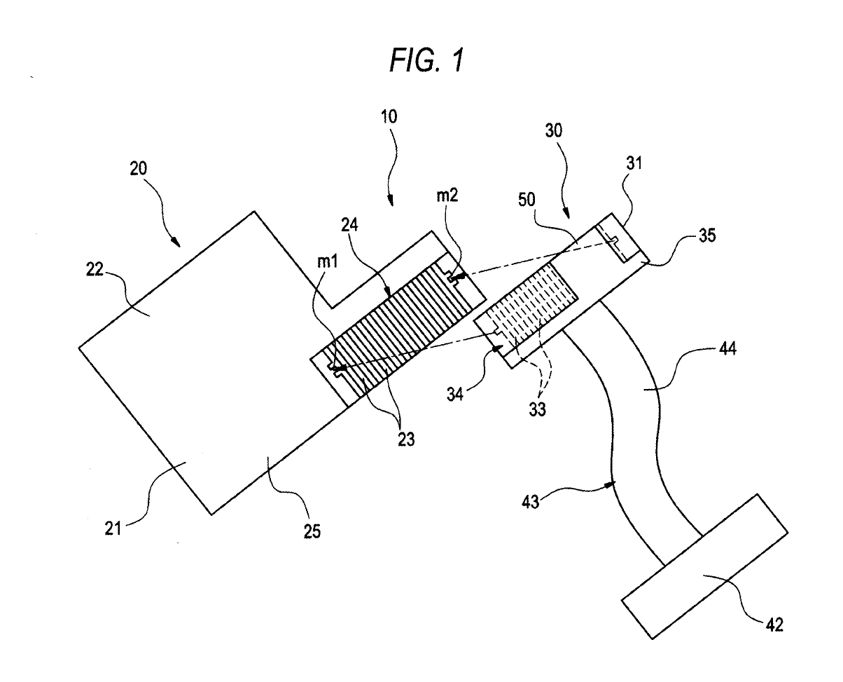

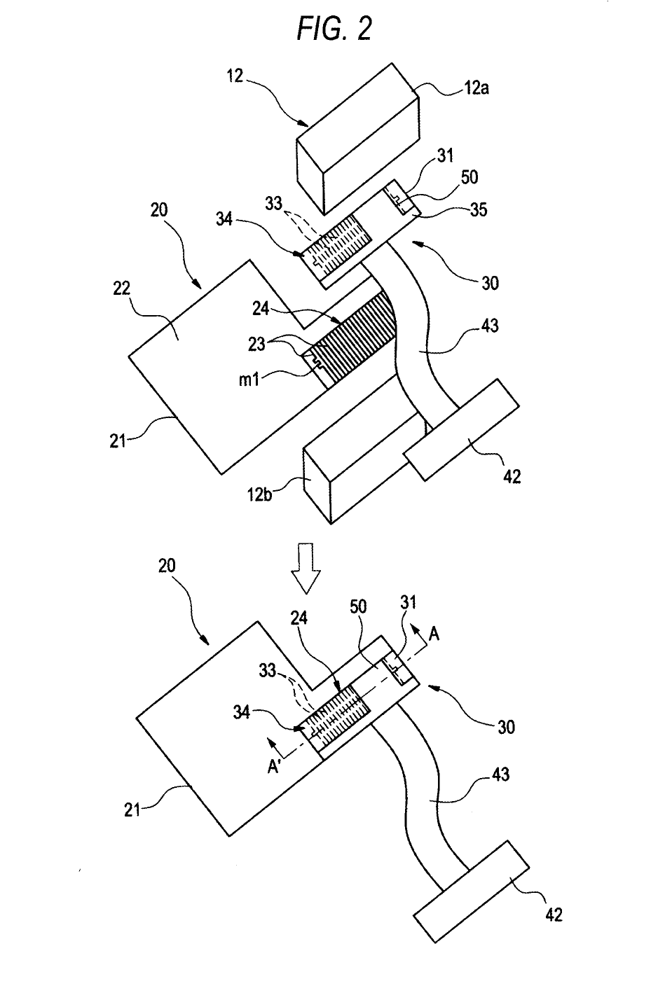

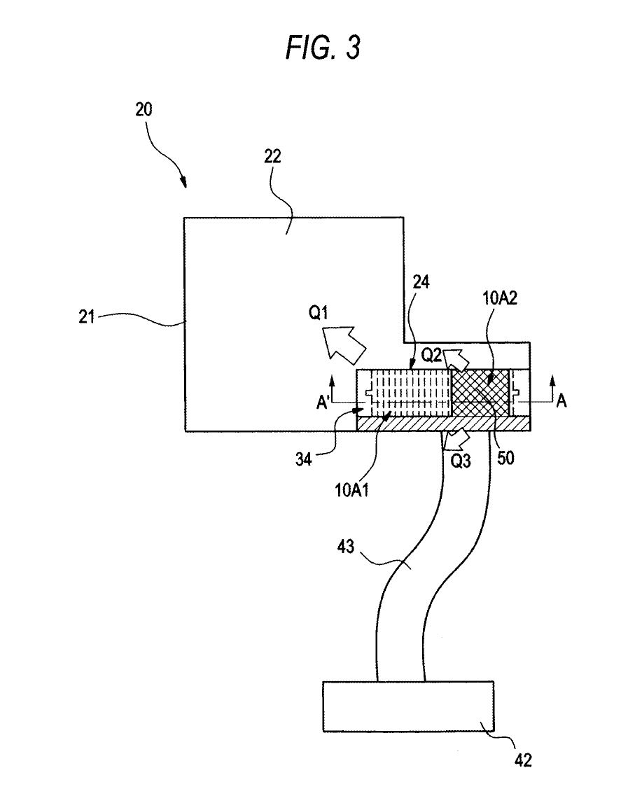

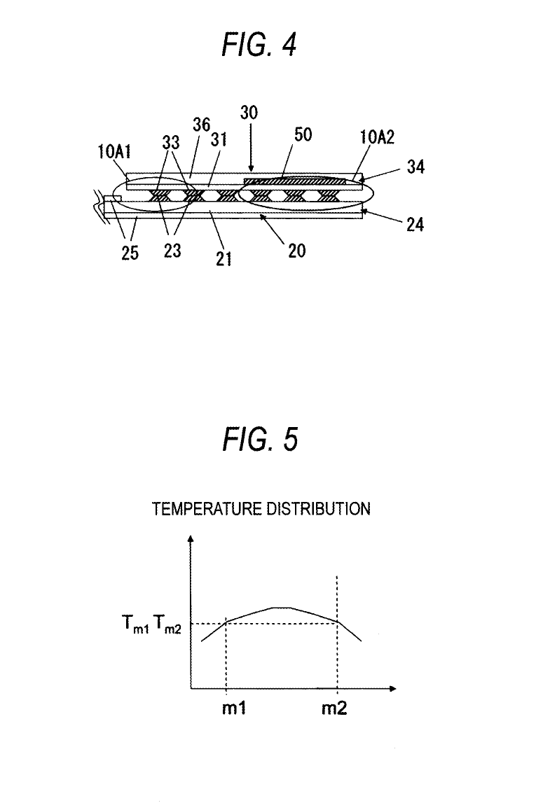

FIG. 1 is an exploded perspective view showing a substrate connecting structure of a first embodiment of the present invention. FIG. 2 is a flow chart for creating the substrate connecting structure. FIG. 3 is a plan view of the substrate connecting structure. FIG. 4 is a cross sectional view taken along line A-A′ shown in FIG. 3.

As shown in FIG. 1, a substrate connecting structure 10 of a first embodiment has a printed circuit board (a first circuit board) 20 and a flexible circuit board (a second circuit board) 30 that are accommodated in an unillustrated upper case of an electronic device. The printed circuit board 20 has a hard base material 21 having the shape of the letter L when viewed in plane. As shown in FIGS. 1 and 3, the printed circuit board 20 has a rectangular mount section 22 and a narrowly elongated connection section 24 (a connecting area). The mount section 22 and the connection section 24 are arranged on a face (a second face) of the hard base material 21 opposing the flexible circuit board 30. A plurality of electronic components are mounted on the rectangular mount section 22. The connection section 24 protrudes from one end of the mount section 22. A plurality of circuit patterns 23 are arranged side by side on the connection section 24 so as to spread to the mount section 22. A cover-lay 25 (or a resist) covering the mount section 22 is arranged on a front face (the second face) and a back face (a first face) that is the other side of the front face, thereby protecting the circuit patterns of the mount section 22. An opening is made in the cover-lay 25, whereby the plurality of circuit patterns 23 are exposed on a front side of the connection section 24.

The flexible circuit board 30 is connected to a function module 42 accommodated in an unillustrated case of the electronic device by a flexible joint section 43 made of a flexible substrate. The flexible circuit board 30 has a soft base material 31 having a substantially the same shape as that of the connection section 24 of the printed circuit board 20. The flexible circuit board 30 has, on a face (a second face) of the soft base material 31 that opposes the printed circuit board 20, a connection section 34 in which a plurality of circuit patterns 33 are arranged side by side and an adjoining section 35 adjoining the connection section 34 along its widthwise direction. The flexible joint section 43 is connected to the connection section 34 through the adjoining section 35 of the flexible circuit board 30. A face of the flexible joint section 43 is covered with a conductive shield 44.

A heat conduction layer 50 having a heat conductivity that is higher than that of the soft base material 31 is partially provided on a back face (a first face) that is the other side of the front face (the second face) of the flexible circuit board 30, in order to increase a quantity of heat dissipated from a region 10A2 remote from the mount section 22 of the printed circuit board 20. In the embodiment, a copper foil arranged on the back face of the soft base material 31 is not entirely etched away but left in part, thereby forming the heat conduction layer 50. The heat conduction layer 50, in detail, is formed so as to extend to the region 10A2 (FIG. 3) that is remote from the mount section 22 and that opposes a portion of the connection section 34; namely, portions of the plurality of circuit patterns 33, through the soft base material 31, and to the adjoining section 35 adjoining the connection section 34. Preferably, an area S2 (an area of a shaded portion of the heat conduction layer 50 shown in FIG. 3) in the adjoining section 35 is greater than an area S1 of the connection section 34 of the heat conduction layer 50 (an area of a lattice portion of the heat conduction layer 50 shown in FIG. 3). The reason for this is that the heat conduction layer having a larger area involves greater heat capacity and better heat conduction, to thereby exhibit a greater heat dissipation effect. The back face of the flexible circuit board 30 is covered with a substantially transparent cover-lay 36 laid over the heat conduction layer 50 (FIG. 4). The thickness of the entire connection section 34 of the flexible circuit board 30 becomes substantially uniform.

Left and right registration marks m1 and m2 are provided on each of the connection section 24 of the printed circuit board 20 and the connection section 34 of the flexible circuit board 30. In order to electrically connect the printed circuit board 20 to the flexible circuit board 30, an unillustrated ACF (anisotropic conductive resin film) is interposed as a conductive connection material between the connection section 24 of the printed circuit board 20 and the connection section 34 of the flexible circuit board 30. The connecting sections 24 and 34 are superposed one on top of the other by means of taking as signs the left and right registration marks m1 and m2 of the respective connecting sections 24 and 34 that can be seen through the cover-lay 36 of the flexible circuit board 30 so that the circuit patterns 23 and 33 overlap each other. In this state, the connecting sections 24 and 34 are sandwiched from the outside by a heat-press tool 12a and a receiving tool 12b of a thermocompression bonding tool 12, thereby subjecting the connecting sections 24 and 34 to pressure and heat for a predetermined period of time. The ACF adhesive is melted by heat from the heat-press tool 12a, whereupon the adhesive squeezed out of spacing between, the circuit patterns 23 and 33 adheres to both the hard base material 21 of the connection section 24 and the soft base material 31 of the connection section 34. The adhesive becomes thermally set, whereby the circuit patterns 23 and 33 are fixed while remaining in plane contact with each other. The printed circuit board 20 and the flexible circuit board 30 are thus electrically connected together.

Since the heat conduction layer 50 is provided on the soft base material 31 of the flexible circuit board 30 so as to extend from a region of the connection section 24 remote from the mount section 22 of the printed circuit board 20 to the adjoining section 35 adjoining the connection section 34. Therefore, on occasion of performance of heat connection, the heat applied to the connection section 24 of the printed circuit board 20 and the connection section 34 of the flexible circuit board 30 transmits not only to the mount section 22 at the region 10A2 remote from the mount block 22 through the hard base material 21 as designated by arrow Q2 but also to the heat conduction layer 50 from the connecting sections 24 and 34 as designated by arrow Q3, further transmitting to the flexible joint section 43 through the heat conduction layer 50. In this case, the area S2 of the adjoining section 35 of the heat conduction layer 50 is set so as to become larger than the area S1 of the connection section 34. Therefore, a quantity of heat transferred for dissipation from the adjoining portion 35 of the heat conduction layer 50 to the flexible joint section 43 can thereby be increased. It thereby becomes possible to prevent buildup of heat in the region 10A2 of the connecting sections 24 and 34 remote from the mount section 22 in the same manner as in the case of the region 10A1 of the connecting sections 24 and 34 close to the mount section 22 (i.e., heat propagates to the mount section 22 through the hard base material 21 as designated by arrow Q1).

As a consequence, as FIG. 5 shows a temperature Tm1 of the area measured at the left registration mark m1 of the region 10A1 of the connecting sections 24 and 34 close to the mount section 22 and a temperature Tm2 of the area measured at the right registration mark m2 of the region 10A2 remote from the mount section 22, a heating temperature of the region 10A1 of the connecting sections 24 and 34 close to the mount section 22 and a heating temperature of the region 10A2 of the connecting sections 24 and 34 remote from the mount section 22 can be made substantially equal to each other, so that unevenness of the heating temperature can be lessened. For this reason, it is possible to prevent occurrence of excessive heating of the region 10A2 of the connecting sections 24 and 34 remote from the mount section 22 and occurrence of a connection failure in the circuit patterns 23 and 33, which would otherwise arise in the region 10A1 close to the mount section 22 for reasons of a heat deficiency, so that a highly accurate connection between the circuit patterns 23 and 33 can be implemented.

The first embodiment shows a case where the circuit patterns 23 of the connection section 24 of the printed circuit board 20 and the circuit patterns 33 of the connection section 34 of the flexible circuit board 30 are connected together by use of an ACF as a conductive connection material. However, the circuit patterns can also be connected together by use of solder that is a hot melt conductive material. Likewise, a failure in connection between the circuit patterns 23 and 33, which would otherwise be caused by non-uniformity in heating temperature, can be prevented.

### Second Embodiment

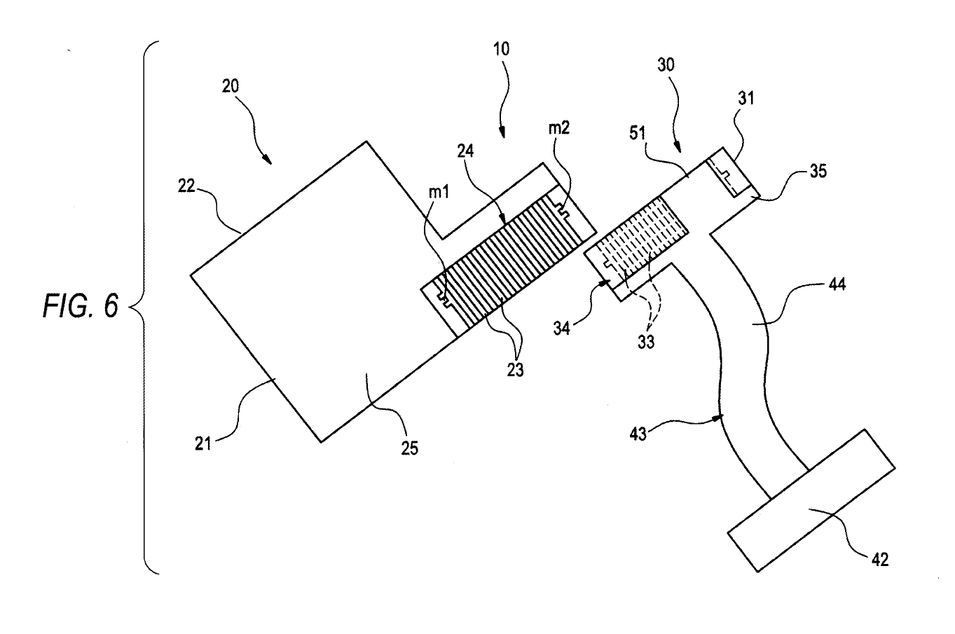

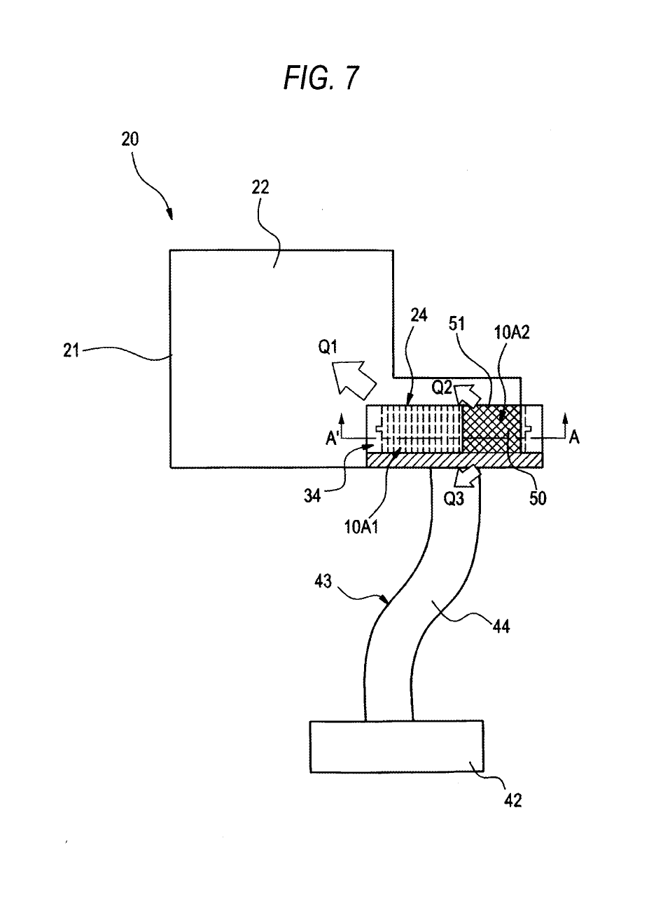

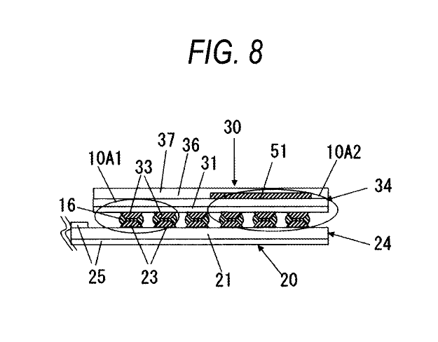

A second embodiment of the present invention is described by reference to FIGS. 6 through 8. FIG. 6 is an exploded perspective view showing a substrate connecting structure of the second embodiment of the present invention. FIG. 7 is a plan view of the substrate connecting structure. FIG. 8 is a cross-sectional view taken along line A-A′ shown in FIG. 7. In FIGS. 6 through 8, elements that are analogous to those described in connection with the first embodiment by reference to FIGS. 1 through 7 are assigned the same reference numerals, and their repeated explanations are omitted.

In the first embodiment, the conductive shield 44 of the flexible joint section 43 is not provided on the back face of the flexible circuit board 30. However, in the second embodiment, a heat conduction layer 51 formed from the conductive shield 44 of the flexible joint section 43 is partially provided over the cover-lay 36 on the back face (the first face) that is the other side of the front face (the second face) corresponding to a side of the flexible circuit board 30 opposing the printed circuit board 20. As in the case with the first embodiment, a range over which the heat conduction layer 51 is laid corresponds to an area extending from a region of the connection section 34, which opposes portions of the plurality of circuit patterns 33 through the soft base material 31 and which is remote from the mount section 22 of the printed circuit board 20, to the adjoining section 35 adjoining the connection section 34. As in the case of the first embodiment, it is preferable that the area S2 of the adjoining section 35 of the heat conduction layer 51 be larger than the area S1 of the connection section 34 of the heat conduction layer 51.

The back face of the flexible circuit board 30 is covered with an overcoat 37 that is a substantially transparent insulating resin film and that is laid over the cover-lay 36 and the heat conduction layer 51 (FIG. 8). A thickness of the overall connection section 34 of the flexible circuit board 30 becomes substantially uniform.

In the second embodiment, the printed circuit board 20 and the flexible circuit board 30 are electrically connected together by use of solder 16 (FIG. 8). At least either the circuit patterns 23 of the connection section 24 of the printed circuit board 20 or the circuit patterns 33 of the connection section 34 of the flexible circuit board 30 are coated with the solder 16 in advance. The connecting sections 24 and 34 are superposed one on top of the other by means of taking as signs the left and right registration marks m1 and m2 of the respective connecting sections 24 and 34 that can be seen through the overcoat 37 of the flexible circuit board 30 so that the circuit patterns 23 and 33 overlap each other. The connecting sections 24 and 34 are nipped, at this time, from the outside by means of the heat-press tool 12a and the receiving tool 12b of the thermocompression bonding tool 12 in the same manner as shown in FIG. 2, thereby subjecting the connecting sections 24 and 34 to pressure and heat for a predetermined period of time. The solder 16 is melted by means of the heat from the heat-press tool 12a, whereupon the circuit patterns 23 and 33 are metal-bonded together as a result of the solder 16 being cooled and solidified. The printed circuit board 20 and the flexible circuit board 30 are electrically connected together.

Since the heat conduction layer 51 is arranged on the soft base material 31 of the flexible circuit board 30 so as to extend from a region of the connection section 24 remote from the mount section 22 of the printed circuit board 20 to the adjoining section 35 adjoining the connection section 34. Therefore, on occasion of performance of heat connection, the heat applied to the connection section 24 of the printed circuit board 20 and the connection section 34 of the flexible circuit board 30 transmits not only to the mount section 22 at the region 10A2 remote from the mount block 22 through the hard base material 21 as designated by arrow Q2 but also to the heat conduction layer 51 from the connecting sections 24 and 34 as designated by arrow Q3, further transmitting to the flexible joint section 43 through the heat conduction layer 51. As in the case with the first embodiment, the area S2 of the adjoining section 35 of the heat conduction layer 51 is set so as to become larger than the area S1 of the connection section 34. Therefore, a quantity of heat transferred for dissipation from the adjoining section 35 of the heat conduction layer 51 to the flexible joint section 43 can thereby be increased. As a result, heat transmits to the mount section 22 through the hard base material 21 as designated by arrow Q1, so that buildup of heat in the region 10A2 of the connecting sections 24 and 34 remote from the mount section 22 can thereby be prevented in the same manner as in the case of the region 10A1 of the connecting sections 24 and 34 close to the mount section 22.

Consequently, as in the case with the first embodiment, the heating temperature of the region 10A1 of the connecting sections 24 and 34 close to the mount section 22 and the heating temperature of the region 10A2 of the connecting sections 24 and 34 remote from the mount section 22 can be made substantially equal to each other. It is therefore possible to prevent occurrence of excessive heating of the region 10A2 of the connecting sections 24 and 34 remote from the mount section 22 and occurrence of a connection failure in the circuit patterns 23 and 33, which would otherwise arise in the region 10A1 close to the mount section 22 for reasons of a heat deficiency, so that a highly accurate connection between the circuit patterns 23 and 33 can be implemented. Moreover, when solder is subjected to excessive heating, a time consumed before the melted solder is cooled to a temperature at which the melted solder becomes solidified increases. However, a problem of excessive heating is eliminated, and hence deterioration of productivity of an electronic device is not induced.

The second embodiment exemplifies a case where the circuit patterns 23 of the connection section 24 of the printed circuit board 20 and the circuit patterns 33 of the connection section 34 of the flexible circuit board 30 are connected together by use of solder as a conductive connection material. However, the circuit patterns can also be connected by use of the ACF as in the case of the first embodiment. Likewise, a failure in connection between the circuit patterns 23 and 33, which would otherwise be caused by non-uniformity in heating temperatures of the connecting sections 24 and 34, can be prevented.

### Third Embodiment

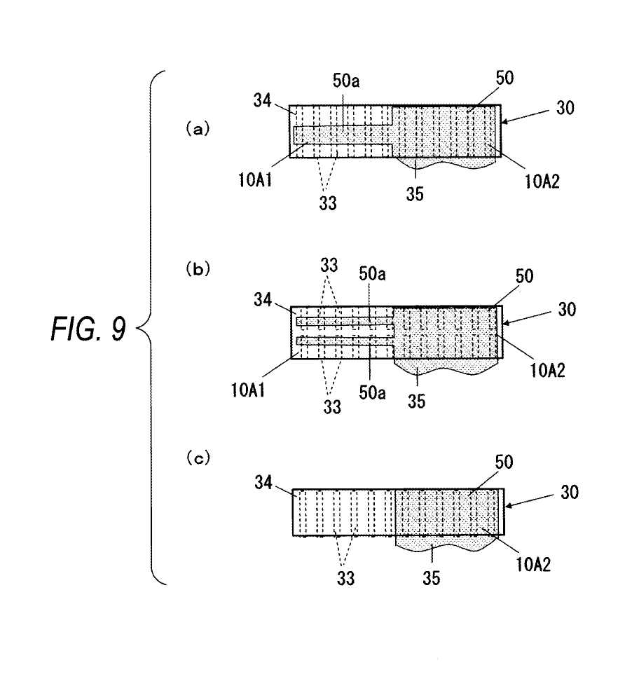

A third embodiment of the present invention is now described by reference to FIG. 9. In the first embodiment, the heat conduction layer 50 of the flexible circuit board 30 is provided only on the remote region 10A2 of the connection section 24, as shown in FIG. 9(c), such that only the region 10A2 of the connecting sections 24 and 34 remote from the mount section 22 of the printed circuit board 20 becomes easy to dissipate heat.

By contrast, in the third embodiment, as shown in FIG. 9(a) or 9(b) the heat conduction layer 50 of the flexible circuit board 30 is formed so as to have strip-shaped heat conduction layers 50a so that the heat conduction layer 50 of the flexible circuit board 30 extends over the entire circuit patterns 33 of the connection section 34.

In the embodiment shown in FIG. 9(a), the heat conduction layer 50 is formed so as to assume a streak of the strip-shaped heat conduction layer 50a elongated to the region 10A1 close to the mount section 22 of the printed circuit board 20. In this case, uniform thickness and rigidity are achieved over the entire connection section 34, so that the entire circuit patterns 33 of the connection section 34 can be substantially, uniformly compression-bonded to the circuit patterns 23 of the connection section 24 of the printed circuit board 20. Further, since the strip-shaped heat conduction layer 50a opposes only portions of the circuit patterns 33, an effect of increasing the quantity of heat dissipated from the region 10A2 of the connecting sections 24 and 34 remote from the mount section 22 of the printed circuit board 20 is not impaired.

The embodiment shown in FIG. 9(b) corresponds to a case where the circuit patterns 33 are arranged in two rows in a longitudinal direction so as to oppose the widthwise direction of the connection section 34. In this case, the heat conduction layer 50 is formed so as to assume two streaks of the strip-shaped heat conduction layer 50a. Even in this case, uniform thickness and rigidity are achieved in the entire connection section 34. The entire circuit patterns 33 of the connection section 34 can be compression-bonded, substantially uniformly, to the circuit patterns 23 of the connection section 24 of the printed circuit board 20.

Although the third embodiment has provided the description about the heat conduction layer 50 formed from a copper foil, the same can also be applied likewise to the heat conduction layer 51 formed from the shield described in connection with the second embodiment. Even in this case, uniform thickness and rigidity are achieved in the entire connection section 34, and the entire circuit pattern 33 of the connection section 34 can be compression-bonded, substantially uniformly, to the circuit patterns 23 of the connection section 24 of the printed circuit board 20.

### Fourth Embodiment

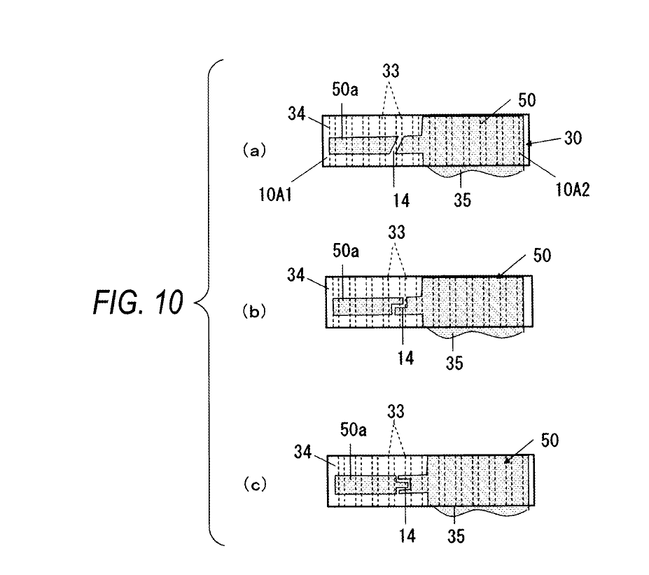

A fourth embodiment of the present invention is described by reference to FIG. 10. In the fourth embodiment, a slit 14 is provided at an arbitrary position along the strip-shaped heat conduction layer 50a in the heat conduction layer 50 of the connection section 34 of the flexible circuit board 30 shown in FIG. 9(a) of the third embodiment, as shown in FIG. 10. The slit 14 is placed at a position where the strip-shaped heat conduction layer 50a transverse the mutually-opposing circuit patterns 33. The slit 14 can assume an appropriate shape, like a shape of a slope (FIG. 10(a)), a shape of a hook (FIG. 10(b)), and a C-shaped geometry (FIG. 10(c)), and the like.

When such a slit 14 is provided at an arbitrary position along the strip-shaped heat conduction layer 50a, heat, conduction effected by the heat conduction layer comes to a stop at the area where the slit 14 is provided. Consequently, so long as the slit 14 is made in the strip-shaped heat conduction layer 50a at a position where a temperature increase is desired, the temperature of the connection section 24 of the printed circuit board 20 and the temperature of the connection section 34 of the flexible circuit board 30 can be increased at that position. Moreover, since the slit 14 transverses the circuit patterns 33, portions of the circuit patterns 33 to be traversed inevitably oppose the heat conduction layer, so that the circuit patterns 33 can be subjected to pressure or heat without fail and that the circuit patterns can be reliably connected.

The fourth embodiment has provided a description about the heat conduction layer 50 formed from copper foil. However, the same can also apply to the heat conduction layer 51 formed from the shield of the second embodiment. Likewise, the slit 14 is provided a portion of the strip-shaped heat conduction layer extended from the heat conduction layer 51, so that the temperature of the connection section 24 and a heat of the connecting sections 24 and 34 can be increased at the position of the slit 14.

### Fifth Embodiment

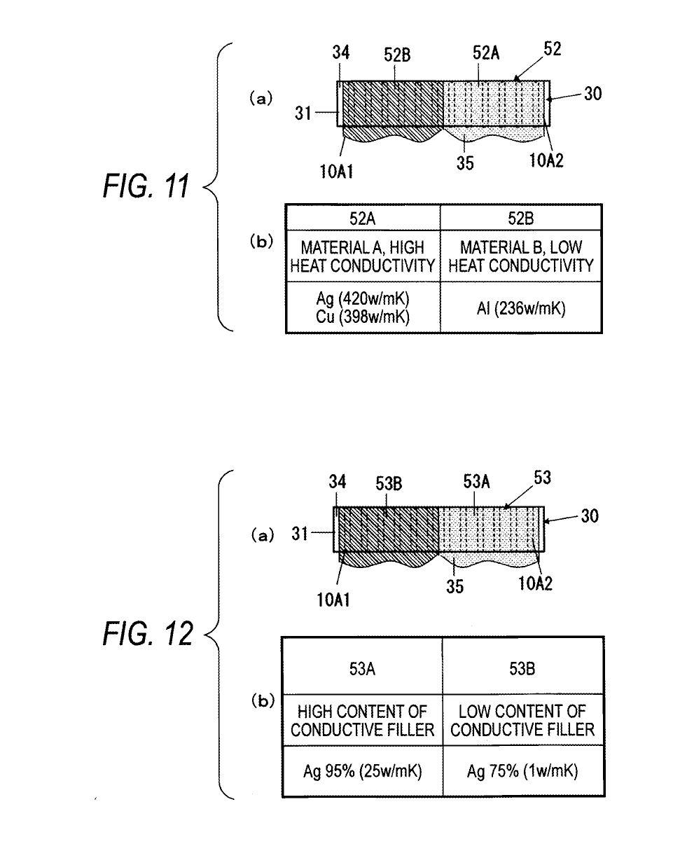

A fifth embodiment of the present invention is described by reference to FIG. 11. In the fifth embodiment, as shown in FIG. 11(a), a heat conduction layer 52 having a first heat conduction layer 52A and a second heat conduction layer 52B is arranged on the back face (the first face) that is the other end of the front face (the second face) of the flexible circuit board 30 opposing the printed circuit board 20 (see FIG. 1), by utilization of the conductive shield 44 of the flexible joint section 43 and in conformance with the second embodiment.

The first heat conduction layer 52A is placed at a region corresponding to a portion of the connection section 34 and a portion of the adjoining section 35; namely, a region of the connection section 34 and a region of the adjoining section 35 that are remote from the mount section 22 of the printed circuit board 20. The first heat conduction layer 52A opposes the circuit patterns 33 of the flexible circuit board 30 through the soft base material 31 at the region 10A2 remote from the mount section 22 of the printed circuit board 20. The second heat conduction layer 52B is placed at a region corresponding to the other portion of the connection section 34 and the other portion of the adjoining section 35 adjoining the connection section 34; namely, in the present embodiment a region of the connection section 34 and a region of the adjoining section 35 that are close to the mount section 22 of the printed circuit board 20, among the connection section 34 and the remaining portion of the adjoining section 35. The second heat conduction layer 52B adjoins the first heat conduction layer 52A. The second heat conduction layer 52B opposes the circuit patterns 33 of the flexible circuit board 30 through the soft base material 31 at the region 10A1 close to the mount section 22 of the printed circuit board 20. When the first heat conduction layer 52A and the second heat conduction layer 52B are arranged side by side, clearance may exist between the heat conduction layers.

The first heat conduction layer 52A has a first quantity of heat conducted per unit time, and the second heat conduction layer 52B has a second quantity of heat conducted per unit time that is smaller than the first quantity of heat conducted. The essential requirement to create the first and second heat conduction layers 52A and 52B having the quantities of heat conducted is to use a material A exhibiting high heat conductivity; for instance, silver (Ag) and copper (Cu), for the first heat conduction layer 52A and a material B exhibiting low heat conductivity; for instance, aluminum (Al), for the first heat conduction layer 52B as shown in FIG. 11(b).

An area SA2 of the first heat conduction layer 52A in the adjoining section 35 is larger than an area SA1 of the first heat conduction layer 52A of the connection section 34. Likewise, an area SB2 of the second heat conduction layer 52B in the adjoining section 35 is larger than an area SB1 of the second heat conduction layer 52B in the connection section 34. A relationship between the area SA1 and the area SA2 and a relationship between the area SB1 and the area SB2 are equal to a relationship between the area S1 and the area S2 described in connection with the first embodiment.

According to the fifth embodiment, the first heat conduction layer 52A that is larger than the second heat conduction layer 52B in terms of a quantity of heat conducted per unit time is placed at a region of the connection section 34 of the flexible circuit board 30 and a region of the adjoining section 35 adjoining the connection section 34 both of which are remote from the mount section 22 of the printed circuit board 20. Hence, the quantity of heat dissipated from the region 10A2 of the connecting sections 24 and 34 of the printed circuit board 20 and the flexible circuit board 30 remote from the mount section 22 of the printed circuit board 20 can be increased. Thus, a heating temperature of the region 10A1 of the connecting sections 24 and 34 close to the mount section 22 and a heating temperature of the region 10A2 of the connecting sections 24 and 34 remote from the mount section 22 can be made substantially equal to each other. The second heat conduction layer 52B that is smaller than the first heat conduction layer 52A in terms of a quantity of heat conducted per unit time is placed at a region of the connection section 34 of the flexible circuit board 30 and a region of the adjoining section 35 adjoining the connection section 34 both of which are remote from the mount section 22 of the printed circuit board 20. Accordingly, a difference between the heating temperature of the connection section 24 and the heating temperature of the connection section 34 can be lessened.

The essential requirement is to selectively use different pieces of metal exhibiting different heat conductivities so as to suit to prepare the first and second heat conduction layers 52A and 52B, respectively. Therefore, the heat conduction layers 52A and 52B can be provided in the same thickness. The entirety of the circuit patterns 33 of the connection section 34 can be uniformly compression-bonded to the circuit patterns 23 of the connection section 24 of the printed circuit board 20.

### Sixth Embodiment

A sixth embodiment of the present invention is described by reference to FIG. 12. In the sixth embodiment, as shown in FIG. 12(a), the flexible circuit board 30 has a heat conduction layer 53 that is made of a conductive shield, that has a first heat conduction layer 53A and a second heat conduction layer 53B, and that is placed on the back face (the first face) which is the other side of the front face (the second face) opposing the printed circuit board 20. A conductive paste containing a conductive filler is used for the conductive shield making up the heat conduction layer. As shown in FIG. 12(b), in the present embodiment, a conductive paste including a high content of silver filler is used for the first heat conduction layer 53A, and a conductive paste including a low content of silver filler is used for the second heat conduction layer 53B. In other respects, the configuration of the sixth embodiment is analogous to that of the fifth embodiment. The reference numerals and symbols shown in FIG. 12(a) that are the same as those shown in FIG. 11(a) designate the same elements.

Even in the sixth embodiment, as in the case of the fifth embodiment, the first heat conduction layer 53A that is larger than the second heat conduction layer 53B in terms of a quantity of heat conducted per unit time is placed at a region of the connection section 34 of the flexible circuit board 30 and a region of the adjoining section 35 adjoining the connection section 34 both of which are remote from the mount section 22 of the printed circuit board 20. Hence, the quantity of heat dissipated from the region 10A2 of the connecting sections 24 and 34 of the printed circuit board 20 and the flexible circuit board 30 remote from the mount section 22 of the printed circuit board 20 can be increased. Thus, a heating temperature of the region 10A1 of the connecting sections 24 and 34 close to the mount section 22 and a heating temperature of the region 10A2 of the connecting sections 24 and 34 remote from the mount section 22 can be made substantially equal to each other. The second heat conduction layer 53B that is smaller than the first heat conduction layer 53A in terms of a quantity of heat conducted per unit time is placed at a region of the connection section 34 of the flexible circuit board 30 and a region of the adjoining section 35 adjoining the connection section 34 both of which are remote from the mount section 22 of the printed circuit board 20. Accordingly, a difference between the heating temperature of the connection section 24 and the heating temperature of the connection section 34 can be lessened.

The essential requirement to prepare the first and second heat conduction layers 53A and 53B is to change a content of conductive filler in the conductive paste. Hence, the heat conduction layers 53A and 53B can be provided in the same thickness. The entirety of the circuit patterns 33 of the connection section 34 can be uniformly compression-bonded to the circuit patterns 23 of the connection section 24 of the printed circuit board 20.

### Seventh Embodiment

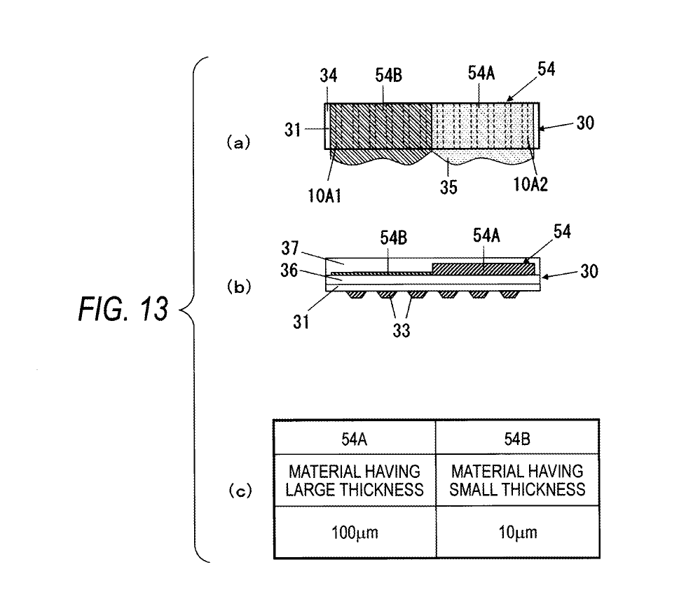

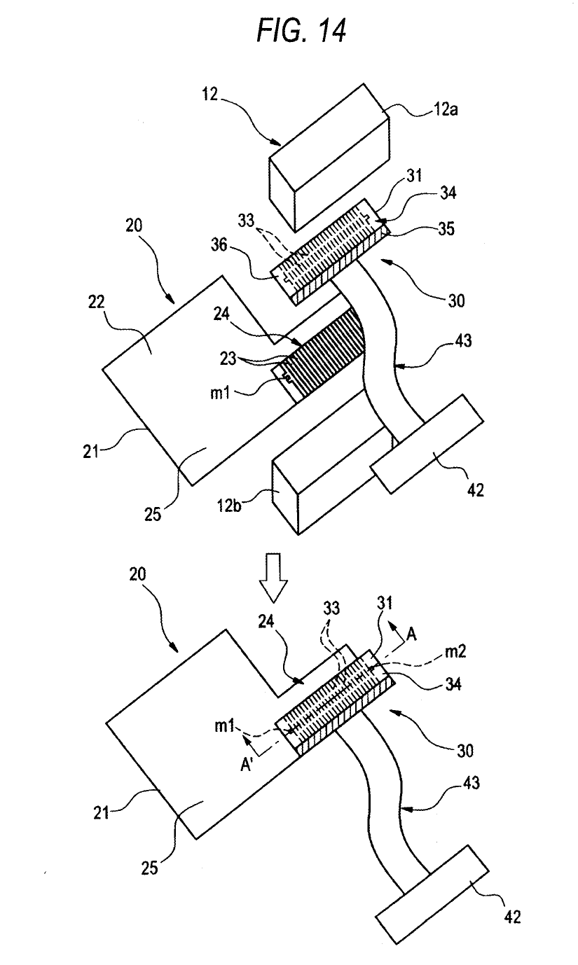

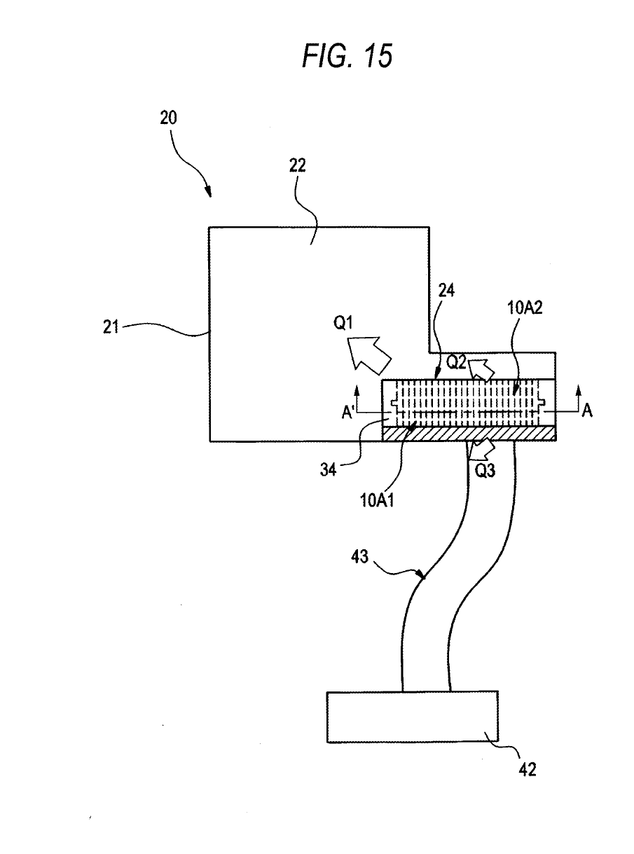

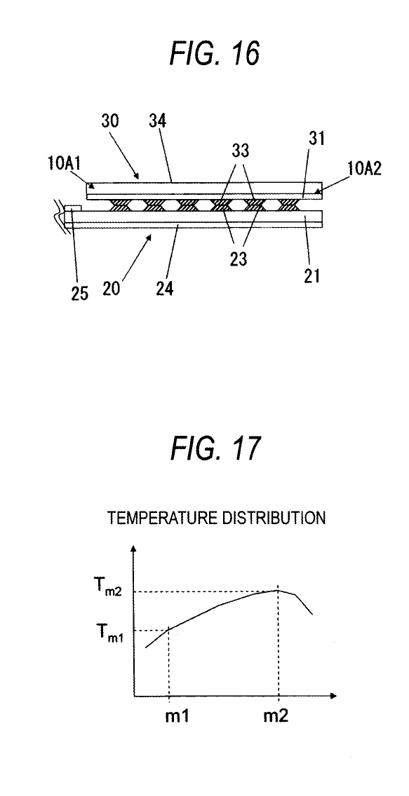

A seventh embodiment of the present invention is described by reference to FIG. 13. As shown in FIGS. 13(a) and (b), the sixth embodiment is characterized in that the heat conduction layer formed from the conductive shield is provided on the back face of the soft base material 31 of the flexible circuit board 30 so as to have different thicknesses. Therefore, a heat conduction layer 54 is configured by a first heat conduction layer 54A and a second heat conduction layer 54B. As shown in FIG. 13(c), a conductive shield material of the first heat conduction layer 52A is given a large thickness, whereas a conductive shield material of the second heat conduction layer 53B is given a smaller thickness. A thickness of the entire flexible circuit board 30 is made substantially uniform by means of the cover-lay 36 and the overcoat 37 covering the heat conduction layer 54. In other respects, the seventh embodiment is analogous to the sixth embodiment in terms of a configuration, and reference numerals and symbols shown in FIG. 13(a) that are the same as those shown in FIG. 12(a) designate the same elements.

Even the seventh embodiment yields a working effect similar to those yielded by the fifth and sixth embodiments.

In the foregoing embodiment, the printed circuit board (the first circuit board) and the flexible circuit board (the second circuit board) are connected together. The present invention is not limited to such a combination of circuit boards and can apply to establish a connection between an arbitrary types of circuit board and a circuit formation component (like an MID).

In the embodiments, the printed circuit board (the first circuit board) is made up of the rectangular mount section 22 and the elongated connection section 24 (the connecting area) protruding out of one end of the mount section 22 and assumes the shape of the letter L when viewed in plane. However, the shape of the circuit board to which the present invention is applied is not limited to such a shape. In the connecting area between two circuit boards, the present invention can be applied to all circuit boards and circuit formation components, like components and boards which would cause non-uniformity in heating temperature during connection operation, such as that shown in FIG. 17.

Although various embodiments of the present invention have been described thus far, the present invention is not limited to the items described in connection with the embodiments. Persons who are versed in the art are also scheduled to make alterations or applications of the invention according to the claims, the descriptions of the specification, and well known techniques, and the inventions also fall within a range to seek protection.

The present patent application is based on Japanese Patent application 2009-196717 filed on Aug. 27, 2009, the entire subject matter of which is incorporated herein by reference.

### INDUSTRIAL APPLICABILITY

The present invention can provide a substrate connecting structure that enables prevention of occurrence of non-uniform temperature increases in connection regions of circuit boards when two circuit boards are thermally bonded by use of a conductive connection material and can also provide an electronic device having the substrate connecting structure.

### DESCRIPTIONS OF THE REFERENCE NUMERALS

10 SUBSTRATE CONNECTING STRUCTURE
10A1 REGION CLOSE TO MOUNT SECTION
10A2 REGION REMOTE FROM MOUNT SECTION
14 SLIT
20 PRINTED CIRCUIT BOARD
21 HARD BASE MATERIAL
22 MOUNT SECTION
23 CIRCUIT PATTERN
24 CONNECTION SECTION (CONNECTING AREA)
30 FLEXIBLE CIRCUIT BOARD
31 SOFT BASE MATERIAL
33 CIRCUIT PATTERN
34 CONNECTION SECTION (CONNECTING AREA)
35 ADJOINING SECTION
43 FLEXIBLE JOINT SECTION
44 SHIELD
50 HEAT CONDUCTION LAYER
50A STRIP-SHAPED HEAT CONDUCTION LAYER
51 HEAT CONDUCTION LAYER
52 TO 54 HEAT CONDUCTION LAYERS
52A TO 54A FIRST HEAT CONDUCTION LAYERS
52B to 54B SECOND HEAT CONDUCTION LAYERS

1. A substrate connecting structure comprising:
a first circuit board including a base material with first and second faces and a plurality of circuit patterns arranged on the second face;
a second circuit board including a base material with first and second faces and a plurality of circuit patterns arranged on the second face;
connecting areas that connect the circuit patterns of the first circuit board and the circuit patterns of the second circuit board through a conductive connection material;
a first heat conduction layer that is arranged on the first face of the second circuit board and that has a first quantity of heat conducted per unit time; and
a second heat conduction layer that is arranged on the first face of the second circuit board while adjoining the first heat conduction layer and that has a second quantity of heat conducted per unit time, the second quantity being smaller than the first quantity,
wherein the first and second heat conduction layers oppose at least part of the plurality of circuit patterns of the second circuit board through the base material of the second circuit board and are arranged so as to extend over at least part of the connecting areas and an area adjoining the connecting areas.

2. The substrate connecting structure according to claim 1, wherein an area of the first heat conduction layer arranged in the area adjoining the connecting areas is greater than an area of the first heat conduction layer arranged in the at least part of the connecting areas.

3. The substrate connecting structure according to claim 2, wherein an area of the second heat conduction layer arranged in the area adjoining the connecting areas is greater than an area of the second heat conduction layer arranged in the at least part of the connecting areas.

4. The substrate connecting structure according to claim 1, wherein the conductive connection material is a hot melt conductive material or a thermosetting conductive resin.

5. The substrate connecting structure according to claim 1, wherein an opening window is provided in the connecting area of the second circuit board;
wherein registration marks are provided in the connecting area of the first circuit board and the connecting area of the second circuit board; and
wherein a state of overlap between the registration mark of the first circuit board and the registration mark of the second circuit board is observable through the opening window.

6. The substrate connecting structure according to claim 1, wherein the first and second heat conduction layers oppose all of the plurality of circuit patterns of the second circuit board and are arranged so as to extend over a substantial entirety of the connecting areas and the area adjoining the connecting areas.

7. The substrate connecting structure according to claim 1, wherein the first and second heat conduction layers are made of a conductive resin.

8. The substrate connecting structure according to claim 7, wherein the conductive resin is arranged also on a flexible substrate connected to the connecting areas.

9. The substrate connecting structure according to claim 1, wherein heat conductivity of a first material making up the first heat conduction layer is greater than heat conductivity of a second material making up the second heat conduction layer.

10. The substrate connecting structure according to claim 1, wherein a quantity of conductive filler contained per unit volume in the first heat conduction layer is greater than a quantity of conductive filler per unit volume in the second heat conduction layer.

11. The substrate connecting structure according to claim 1, wherein a thickness of the first heat conduction layer is greater than a thickness of the second heat conduction layer.

12. An electronic device having the substrate connecting structure according to claim 1.
